(19) United States
(12) Patent Application Publication
(10) Pub. No.: US 2026/0165055 A1
(43) Pub. Date: Jun. 11, 2026

(54) ETCHING METHOD, METHOD OF MANUFACTURING SEMICONDUCTOR DEVICE, AND ETCHING APPARATUS

(71) Applicant: Kioxia Corporation, Tokyo (JP)

(72) Inventors: Hironobu SATO, Yokohama Kanagawa (JP); Yusuke SATO, Ama Aichi (JP); Kentaro MATSUNAGA, Yokkaichi Mie (JP)

(73) Assignee: Kioxia Corporation, Tokyo (JP)

(21) Appl. No.: 19/328,388

(22) Filed: Sep. 15, 2025

(30) Foreign Application Priority Data
Dec. 10, 2024 (JP) 2024-215917

(51) Int. Cl. H01L 21/311; H01L 21/3065; H01L 21/78

(52) U.S. Cl. CPC H10P 50/283; H10P 50/242; H10P 54/00

(57) ABSTRACT

An etching method with HF gas and a catalyst is provided. According to one embodiment, the etching method includes: a step of providing a catalytic layer 2 on a substrate 1 that contains silicon as a principal component; a step of exposing the substrate 1 provided with the catalytic layer 2, to an HF gas atmosphere; and a step of irradiating the substrate 1 in the HF gas atmosphere with light, and etching the substrate 1 in contact with the catalytic layer 2.

### CROSS-REFERENCE TO RELATED APPLICATION

This application is based upon and claims the benefit of priority from Japanese Patent Application No. 2024-215917, filed Dec. 10, 2024, the entire contents of which are incorporated herein by reference.

### FIELD

Embodiments described herein relate generally to an etching method, a method of manufacturing a semiconductor device, and an etching apparatus.

### BACKGROUND

One of silicon etching methods is reactive ion etching (RIE).

### BRIEF DESCRIPTION OF THE DRAWINGS

FIG. 1 schematically shows an etching method for silicon oxide and silicon according to a first embodiment.

FIG. 2 is a flowchart of catalyst-etching silicon oxide and silicon according to the first embodiment.

FIG. 3 schematically shows each step of catalyst-etching silicon oxide and silicon in the etching method according to the first embodiment.

FIG. 4 schematically shows each step of pattern formation on a catalytic layer in a case where resist contains no catalyst in the etching method according to the first embodiment.

FIG. 5 is a block diagram showing an example of the entire configuration of a semiconductor device manufactured using the etching method according to the first embodiment.

FIG. 6 is a circuit diagram showing an example of a circuit configuration of a memory cell array included in the semiconductor device manufactured using the etching method according to the first embodiment.

FIG. 7 is a sectional view showing an example of a sectional configuration of the semiconductor device manufactured using the etching method according to the first embodiment.

FIG. 8 is a sectional view of a region RA in FIG. 7.

FIG. 9 is a sectional view showing an example of a sectional structure of a cell region of the memory cell array included in the semiconductor device manufactured using the etching method according to the first embodiment.

FIG. 10 is a sectional view taken along line X-X of FIG. 9.

FIG. 11 is a flowchart showing an example of a method of manufacturing the semiconductor device using the etching method according to the first embodiment.

FIG. 12 is a sectional view showing a step of manufacturing the semiconductor device using the etching method according to the first embodiment.

FIG. 13 is a sectional view showing a step of manufacturing the semiconductor device using the etching method according to the first embodiment.

FIG. 14 is a sectional view showing a step of manufacturing the semiconductor device using the etching method according to the first embodiment.

FIG. 15 is a sectional view showing a step of manufacturing the semiconductor device using the etching method according to the first embodiment.

FIG. 16 is a sectional view showing a step of manufacturing the semiconductor device using the etching method according to the first embodiment.

FIG. 17 is a sectional view showing a step of manufacturing the semiconductor device using the etching method according to the first embodiment.

FIG. 18 is a sectional view showing a step of manufacturing the semiconductor device using the etching method according to the first embodiment.

FIG. 19 is a sectional view showing a step of manufacturing the semiconductor device using the etching method according to the first embodiment.

FIG. 20 is a sectional view showing a step of manufacturing the semiconductor device using the etching method according to the first embodiment.

FIG. 21 shows an example of a configuration of an etching apparatus used for catalyst etching according to a second embodiment.

### DETAILED DESCRIPTION

One embodiment of the present invention provides an etching method with HF gas and a catalyst.

In general, according to one embodiment, an etching method includes: a step of providing a catalytic layer on a substrate that contains silicon as a principal component; a step of exposing the substrate provided with the catalytic layer, to an HF gas atmosphere; and a step of irradiating the substrate in the HF gas atmosphere with light, and etching the substrate in contact with the catalytic layer.

Embodiments are described below with reference to the drawings. Note that in the following description, configuration elements having the same function and configuration are assigned a common reference symbol. In a case of distinguishing a plurality of configuration elements having a common reference symbol, the common reference symbol is assigned indices to distinguish the elements from each other. Note that in a case where the configuration elements are not required to be distinguished, these configuration elements are only assigned a common reference symbol but are assigned no index. Here, the indices are not limited to subscripts or superscripts, and include, for example, a lowercased letter added at the end of a reference symbol, and an index that means an array.

### 1. First Embodiment

### 1.1 Etching Method for Silicon Oxide and Silicon

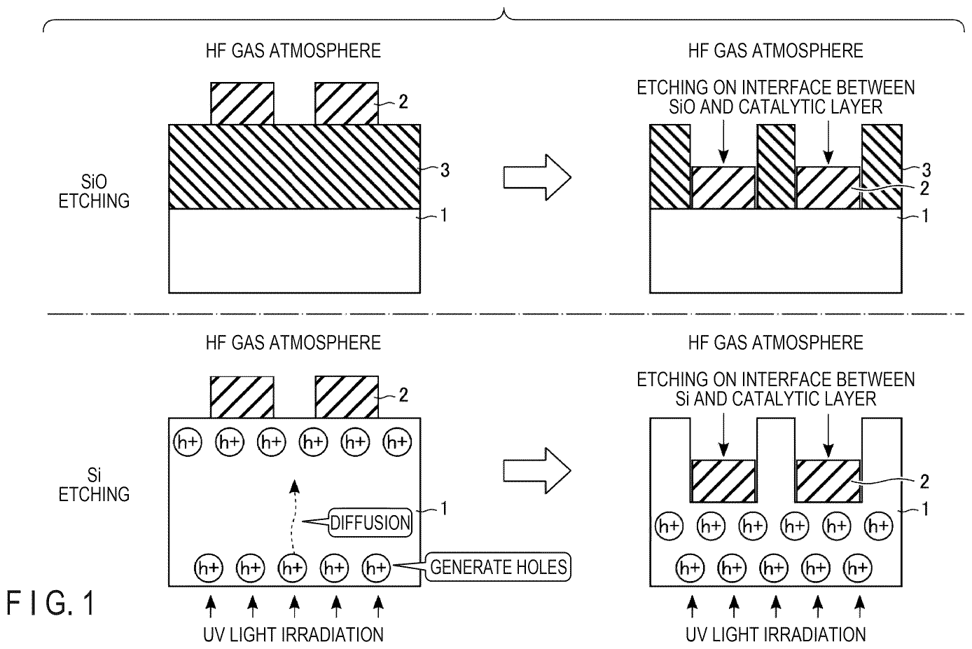

First, referring to FIG. 1, an etching method for silicon oxide (SiO) and silicon (Si) is described as an example. FIG. 1 schematically shows an etching method for silicon oxide and silicon.

In the present embodiment, as one of etching methods for silicon oxide and silicon, etching using a catalyst (hereinafter, also represented as “catalyst etching”) is described. Note that a material serving as a target of catalyst etching is not limited to silicon oxide and silicon. For example, catalyst etching is also applicable to silicon nitride (SiN).

As shown in the upper part of FIG. 1, for example, in a case of catalyst-etching silicon oxide 3 (e.g., a first layer) formed on a silicon substrate 1, a pattern of a catalytic layer 2 is formed on an upper surface of the silicon oxide 3. The silicon substrate 1 is a substrate that contains silicon as a principal component, and is, for example, a silicon wafer. The silicon substrate 1 may contain impurities. The silicon oxide 3 is a layer that contains silicon and oxygen. A material that is hydrogen-bonded to hydrogen fluoride (HF) gas by a catalytic reaction is used for the catalytic layer 2. For example, the hydroxyl group (—OH) of phenol is hydrogen-bonded to HF. In the following description, a case where the catalytic layer 2 is made of novolac resin, which contains phenol (phenol novolac resin), is described. For example, resist that contains novolac resin can be used for photolithography using the g-line or i-line. For example, in a case where resist that contains novolac resin is used as the catalytic layer 2, a pattern of the catalytic layer 2 can be formed by photolithography. Note that the functional group that is hydrogen-bonded to HF is not limited to the hydroxyl group (—OH). The catalytic layer 2 is not limited to novolac resin. The details of materials for the catalytic layer 2 other than novolac resin are described later.

When the silicon substrate 1 provided with the silicon oxide 3 on which the catalytic layer 2 is formed is exposed to an HF gas atmosphere, the catalytic layer 2 is hydrogen-bonded to HF in the HF gas. Hydrogen-bonded HF molecules have a greater interatomic distance between H and F than that in a normal state. The HF molecules with an increased interatomic distance between H and F are more reactive than HF molecules in the normal state. Accordingly, the silicon oxide 3 in contact with the catalytic layer 2 is preferentially etched by HF. As the catalytic layer 2 descends into the etched silicon oxide 3, the silicon oxide 3 is anisotropically etched. The reaction formula between silicon oxide (SiO₂) and HF in this case is indicated by Formula (1).

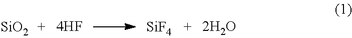

As shown in the lower part of FIG. 1, for example, in the case of catalyst-etching the silicon substrate 1, the pattern of the catalytic layer 2 is formed on the upper surface of the silicon substrate 1. The material of the catalytic layer 2 is the same as that in the case of catalyst-etching the silicon oxide 3. Note that the silicon oxide 3 and the silicon substrate 1 may be sequentially etched. A layer that is different from the silicon oxide 3 or the silicon substrate 1 may be formed between the silicon oxide 3 and the silicon substrate 1.

In the case of etching silicon by HF gas, when holes are supplied as the reaction formula indicated by Formula (2), etching relatively easily proceeds.

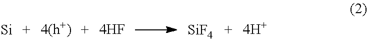

Here, h⁺ indicates a hole. H⁺ indicates a hydrogen ion.

SiF₄ generated by Formula (2) transitions to a reaction indicated by Formula (3).

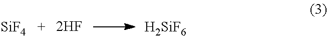

According to the reactions indicated by Formulae (2) and (3), silicon in contact with the catalytic layer 2 is more preferentially etched than silicon that is not in contact with the catalytic layer 2.

In the present embodiment, the back surface of the silicon substrate 1 is irradiated with ultraviolet (UV) light, thus generating holes H⁺ in the silicon substrate 1. Note that light (electromagnetic waves) with which the silicon substrate 1 is irradiated is not limited to UV light. The light with which the silicon substrate 1 is irradiated may be what has a wavelength 1,100 nm or less. Consequently, the types of light with which the silicon substrate 1 can be irradiated include visible light. Any type of light with a wavelength of 1,100 nm or less can generate holes h⁺. Holes h⁺ generated by UV light irradiation diffuse in the silicon substrate 1, and reach the interface between the catalytic layer 2 and the silicon substrate 1.

When the silicon substrate 1 on which the catalytic layer 2 is formed is exposed to the HF gas atmosphere in this case, the catalytic layer 2 is hydrogen-bonded to HF. Silicon in contact with the catalytic layer 2 is preferentially etched by HF molecules having an increased interatomic distance between H and F. As the catalytic layer 2 descends into the etched silicon substrate 1, the silicon substrate 1 is anisotropically etched.

The catalytic layer 2 may be made of any material that has a functional group that is hydrogen-bonded to HF by a catalytic reaction. The catalytic layer 2 contains a hydroxyl group (—OH), a carboxyl group (—COOH), an amino group (—NH₂), an amide group (—CONH₂), a nitro group (—NO₂), or an ether bond (ether group) (—O—), as a functional group that is hydrogen-bonded to HF. As used herein, the term “or” is not necessarily an exclusive term, e.g., “A or B” would include A, B, or A and B.

The catalytic layer 2 with a hydroxyl group (—OH) other than that with phenol contains at least one of poly(vinyl alcohol) (PVA), poly(hydroxyethyl methacrylate) (PHEMA), poly(hydroxystyrene) (PHS), poly(vinyl acetate-co-vinyl alcohol) (PVAc-Vac), and poly(4-hydroxystyrene-co-methyl methacrylate) (PHS-MMA).

The catalytic layer 2 with a carboxyl group (—COOH) contains at least one of poly(methacrylic acid) (PMAA), poly(acrylic acid) (PAA), poly(itaconic acid) (PIA), poly(styrene-co-maleic acid) (PSMA), poly(4-vinylbenzoic acid) (PVBA), poly(4-acryloylbenzoic acid) (PABA), poly(4-carboxystyrene) (PCS), poly(ethylene glycol monomethacrylate-co-methacrylic acid) (PEGMA-MAA), poly(ethylene glycol monomethacrylate-co-acrylic acid) (PEGMA-AA), and poly(ethylene glycol monomethacrylate-co-itaconic acid) (PEGMA-IA).

The catalytic layer 2 with an amino group (—NH₂) contains at least one of poly(4-aminostyrene) (PAS), poly(allyl amine) (PAA), poly(ethyleneimine) (PEI), poly(2-aminoethyl methacrylate) (PAEMA), poly(vinyl amine) (PVAm), poly(3-aminophenylboronic acid) (PAPBA), poly(2-aminoethyl acrylate) (PAEA), poly(4-vinylbenzylamine) (PVBA), poly(N,N-dimethyl aminoethyl methacrylate) (PDMAEMA), and poly(allylamine-co-acrylic acid) (PAA-AA).

The catalytic layer 2 with an amide group (—CONH₂) contains at least one of polyacrylamide (PAM), poly(N-isopropylacrylamide) (PNIPAM), poly(N-vinylpyrrolidone-co-acrylamide) (PVP-AAm), poly(N,N-dimethylacrylamide) (PDMA), poly(acrylamide-co-methacrylic acid) (PAM-MAA), poly(N-phenylacrylamide) (PPAM), poly(acrylamide-co-acrylic acid) (PAM-AA), poly(N-(2-hydroxyethyl)acrylamide) (PHEA), poly(N-acryloyl glycine) (PAG), and poly(N-methacryloyl glycine) (PMAG).

The catalytic layer 2 with a nitro group (—NO₂) contains at least one of poly(2-nitrobenzyl methacrylate) (PNBMA), poly(2-nitrobenzyl acrylate) (PNBA), poly(4-nitrobenzyl methacrylate) (PNBMA), poly(4-nitrobenzyl acrylate) (PNBA), poly(2-nitrobenzyl methacrylamide) (PNBMAm), poly(2-nitrobenzyl acrylamide) (PNBAm), poly(4-nitrobenzyl methacrylamide) (PNBMAm), poly(4-nitrobenzyl acrylamide) (PNBAm), poly(2-nitrobenzyl vinyl ether) (PNBVE), and poly(4-nitrobenzyl vinyl ether) (PNBVE).

The catalytic layer 2 with an ether group (—O—) contains at least one of poly(ethylene glycol) (PEG), poly(propylene glycol) (PPG), poly(ethylene oxide) (PEO), poly(propylene oxide) (PPO), poly(ethylene glycol dimethacrylate) (PEGDMA), poly(propylene glycol dimethacrylate) (PPGDMA), poly(ethylene glycol methacrylate) (PEGMA), poly(propylene glycol methacrylate) (PPGMA), poly(ethylene oxide-co-propylene oxide) (PEO-PPO), and poly(ethylene glycol vinyl ether) (PEGVE).

The catalytic layer 2 may contain poly(vinylphenol) (PVP), and may contain at least one of naphthol novolac resin, resorcinol novolac resin, and dihydroxynaphthalene novolac resin. Furthermore, the catalytic layer 2 may contain naphthoquinone-diazido (NQD).

The catalytic layer 2 may contains a low molecular weight oligomer, for example, with molecular weight 100˜1000, including phenolic low molecular weight oligomer. The catalytic layer 2 may contains phenolic dendrimer. The catalytic layer 2 may contains a cyclic oligomer including at least one of, phenolic cyclic oligomer, resorcinol cyclic oligomer, naphthol cyclic oligomer, and dihydroxynaphthalene cyclic oligomer.

### 1.2 Flow of Catalyst-Etching During Etching of Silicon Oxide and Silicon

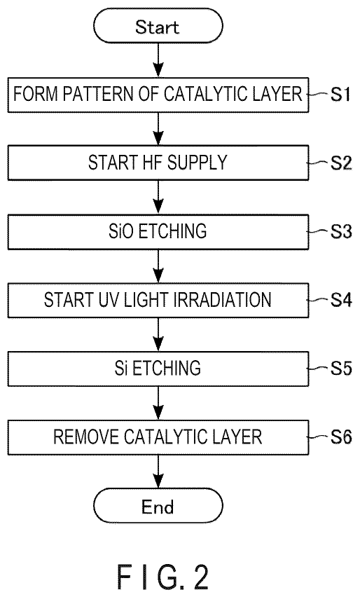

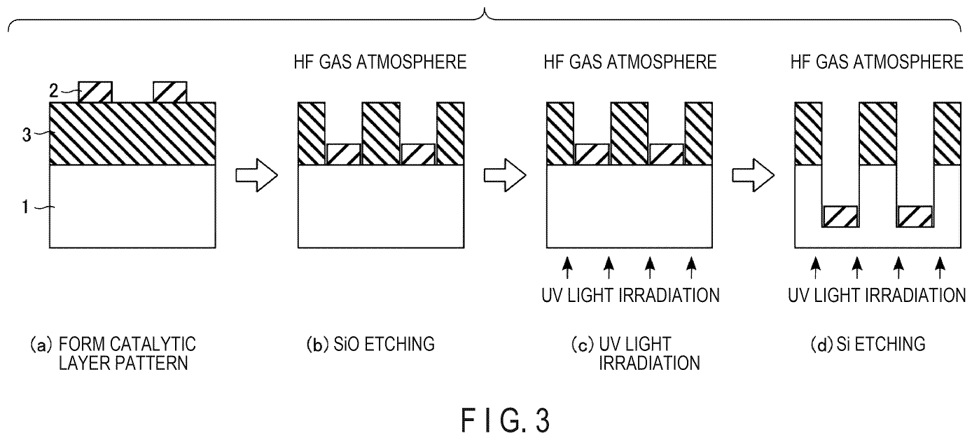

Next, referring to FIGS. 2 and 3, the flow of catalyst etching in a case where silicon oxide and silicon are etched. FIG. 2 is a flowchart of catalyst-etching silicon oxide and silicon. FIG. 3 schematically shows each step of catalyst-etching silicon oxide and silicon.

In the catalyst-etching silicon oxide and silicon, Steps S1 to S6 shown in FIG. 2 are sequentially executed. The steps are sequentially described.

### <Step S1>

As shown in the part (a) of FIG. 3, first, a pattern of the catalytic layer 2 is formed on the silicon oxide 3. For example, the catalytic layer 2 is made of resist that contains novolac resin and is for g-line (or i-line). In this case, a resist mask formed by photolithography functions as the catalytic layer 2.

### <Step S2>

Next, HF gas supply to the silicon oxide 3 and the silicon substrate 1 is started. That is, the silicon oxide 3 is exposed to an HF gas atmosphere.

### <Step S3>

As shown in the part (b) of FIG. 3, in the HF atmosphere, the silicon oxide 3 in contact with the catalytic layer 2 is etched. After the silicon oxide 3 is etched, the bottom surface of the catalytic layer 2 is in contact with the silicon substrate 1. That is, in this stage, the catalytic layer 2 is provided on the silicon substrate 1.

### <Step S4>

As shown in the part (c) of FIG. 3, in the HF atmosphere, in the state where the catalytic layer 2 is provided on the silicon substrate 1, irradiation of the silicon substrate 1 with UV light is started. Accordingly, holes h⁺ are generated in the silicon substrate 1.

### <Step S5>

As shown in the part (d) of FIG. 3, in the HF atmosphere, the silicon substrate 1 in contact with the catalytic layer 2 is etched.

### <Step S6>

Lastly, the catalytic layer 2 is removed, and the catalyst-etching is finished.

Note that in the flowchart shown in FIG. 2, the case of starting the irradiation with UV light in Step S4 after etching of the silicon oxide 3 in Step S3 is described. Alternatively, the timing of starting the irradiation with UV light may be at the same time as the start of HF gas supply in Step S2, or during etching of the silicon oxide 3.

### 1.3 Pattern Formation of Catalytic Layer in Case Where Resist Contains No Material of Catalytic Layer

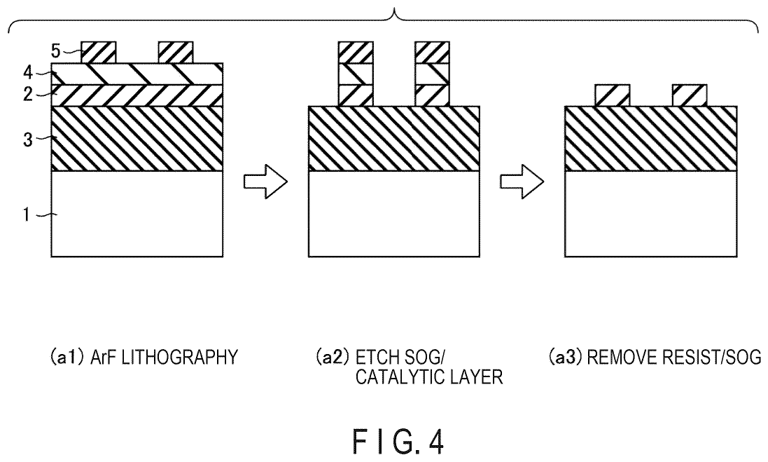

Next, referring to FIG. 4, an example of pattern formation of the catalytic layer 2 in a case where the resist contains no material of the catalytic layer 2 is described. FIG. 4 schematically shows each step of pattern formation of the catalytic layer in the case where the resist contains no catalyst.

In Step S1 described with reference to FIG. 2, the operations of (a1) to (a3) of FIG. 4 are sequentially executed.

As shown in the part (a1) of FIG. 4, first, the catalytic layer 2 is film-formed on the silicon oxide 3. For example, the catalytic layer 2 is made of SOC (Spin on Carbon). Next, SOG (Spin on Glass) 4 is film-formed on the catalytic layer 2. The SOG 4 functions as a mask when the catalytic layer 2 is etched. Next, resist 5 is applied, and a pattern of the resist 5 is formed by photolithography using ArF excimer laser.

As shown in the part (a2) of FIG. 4, next, the resist 5 is used as a mask, and the SOG 4 and the catalytic layer 2 are etched.

As shown in the part (a3) of FIG. 4, when the resist 5 and the SOG 4 are removed, the pattern of the catalytic layer 2 is formed. Subsequent operations are similar to those of Steps S2 to S6 described with reference to FIG. 2. According to the present method, a finer pattern of the catalytic layer 2 can be formed than that in a case of using resist that contains novolac resin and is for g-line or i-line, for example.

### 1.4 Application Example to Semiconductor Device Manufacturing Method

Next, an example of application of catalyst etching to a semiconductor device manufacturing method is described. In this example, a case where the semiconductor device is a three-dimensional stacked NAND flash memory is described. A case where the catalyst etching in the present embodiment is applied to a dicing step for the NAND flash memory is described below. Note that the semiconductor device is not limited to the NAND flash memory. The catalyst etching is also applicable to any of steps other than dicing.

### 1.4.1 Entire Configuration of Semiconductor Device

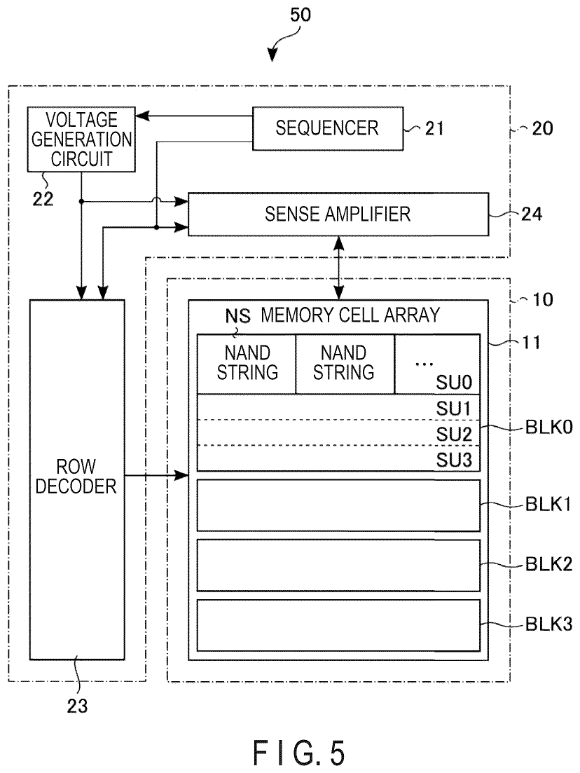

First, referring to FIG. 5, an example of the entire configuration of a semiconductor device 50 is described. FIG. 5 is a block diagram showing an example of the entire configuration of the semiconductor device 50. Note that in FIG. 5, parts of connection between the configuration elements are indicated by arrows. However, the connections between the configuration elements are not limited thereto.

As shown in FIG. 5, the semiconductor device 50 includes an array chip 10, and a circuit chip 20. The semiconductor device 50 has a structure where the array chip 10 and the circuit chip 20 are bonded to each other (hereinafter, represented as “bonded structure”). Note that the semiconductor device 50 does not necessarily have a bonded structure. The semiconductor device 50 may have a structure where circuits and memory cell arrays are formed on a semiconductor substrate.

The array chip 10 is a chip provided with arrays of nonvolatile memory cell transistors. The circuit chip 20 is a chip provided with a circuit that controls the array chip 10. Note that a plurality of array chips 10 may be provided. In this case, the plurality of array chips 10 may be bonded onto the circuit chip 20 in a stacked manner.

The array chip 10 includes one or more memory cell arrays 11. The memory cell array 11 is a region in which nonvolatile memory cell transistors are three-dimensionally disposed. In the example shown in FIG. 5, the array chip 10 includes one memory cell array 11.

The circuit chip 20 includes a sequencer 21, a voltage generation circuit 22, a row decoder 23, and a sense amplifier 24.

The sequencer 21 is a control circuit for the semiconductor device 50. For example, the sequencer 21 is connected to the voltage generation circuit 22, the row decoder 23, and the sense amplifier 24. The sequencer 21 controls the voltage generation circuit 22, the row decoder 23, and the sense amplifier 24. The sequencer 21 controls the entire operation of the semiconductor device 50, based on control by an external controller. More specifically, the sequencer 21 executes a write operation, a read operation, an erase operation and the like.

The voltage generation circuit 22 is a circuit that generates the voltages used for the write operation, the read operation, the erase operation and the like. For example, the voltage generation circuit 22 is connected to the row decoder 23 and the sense amplifier 24. The voltage generation circuit 22 supplies the generated voltages to the row decoder 23, the sense amplifier 24 and the like.

The row decoder 23 is a circuit that decodes the row addresses. The row address is an address signal that designates lines (a word line and a select gate line described later) in the row direction of the memory cell array 11. Based on the row address decoded result, the row decoder 23 supplies the memory cell array 11 with the voltage applied by the voltage generation circuit 22.

The sense amplifier 24 is a circuit that writes and reads data. In the read operation, the sense amplifier 24 senses data read from the memory cell array 11. In the write operation, the sense amplifier 24 supplies the memory cell array 11 with the voltage according to write data.

Next, the internal configuration of the memory cell array 11 is described. The memory cell array 11 includes a plurality of blocks BLK. Each block BLK is an aggregation of a plurality of memory cell transistors where data is collectively erased. The plurality of memory cell transistors in the block BLK are associated with rows and columns. In the example shown in FIG. 5, the memory cell array 11 includes four blocks BLK0, BLK1, BLK2, and BLK3.

Each block BLK includes a plurality of string units SU. Each string unit SU is, for example, an aggregation of a plurality of NAND strings that are collectively selected in the write operation or the read operation. The NAND string includes a plurality of memory cell transistors connected in series. In the example shown in FIG. 5, each block BLK includes four string units SU0, SU1, SU2, and SU3. Note that the number of blocks BLK included in each memory cell array 11, and the number of string units SU included in each block BLK may be freely defined.

### 1.4.2 Circuit Configuration of Memory Cell Array

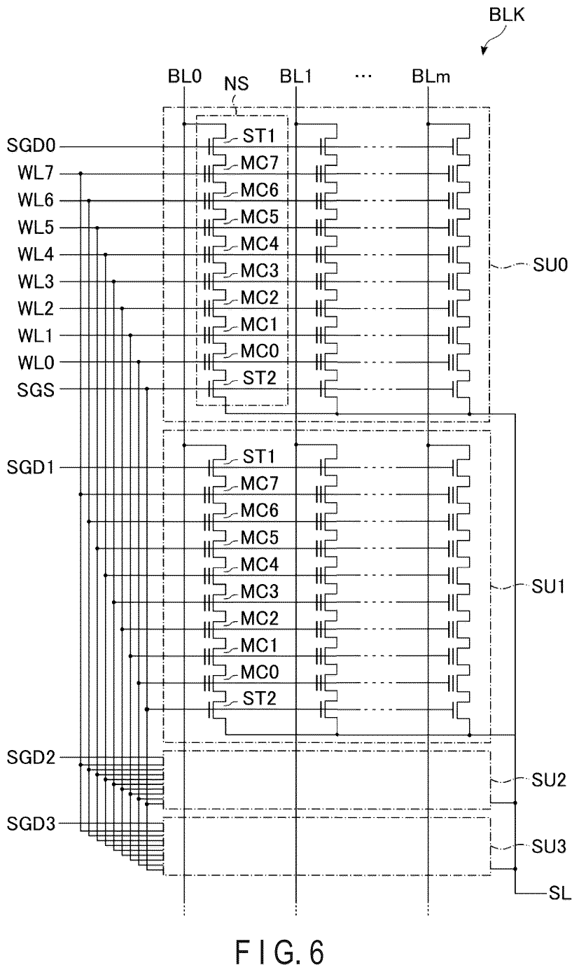

Next, referring to FIG. 6, an example of the circuit configuration of the memory cell array 11 is described. FIG. 6 shows a circuit diagram showing an example of the circuit configuration of the memory cell array 11. The example shown in FIG. 6 indicates the circuit diagram of one block BLK.

As shown in FIG. 6, the string unit SU includes a plurality of NAND strings NS. Each of the NAND strings NS in the string unit SU is connected to any of the bit lines BL0 to BLm (m is an integer of one or more).

The NAND string NS includes a plurality of memory cell transistors MC, and select transistors ST1 and ST2. In the example shown in FIG. 6, the NAND string NS includes eight memory cell transistors MC0 to MC7. Note that the number of memory cell transistors MC included in the NAND string NS may be freely defined.

The memory cell transistor MC is a memory element that stores data in a nonvolatile manner. The memory cell transistor MC includes a control gate and a charge storage film. The memory cell transistor MC may be of a MONOS (Metal-Oxide-Nitride-Oxide-Silicon) type or an FG (Floating Gate) type. The MONOS type uses an insulating layer as a charge storage film. The FG type uses a conductor as a charge storage film. The case where the memory cell transistor MC is of the MONOS type is described below.

The select transistors ST1 and ST2 are switching elements. The select transistors ST1 and ST2 are used to select the string unit SU in various operations.

The current paths of the select transistor ST2, the memory cell transistors MC0 to MC7, and the select transistor ST1 in the NAND string NS are connected in series. The drain of the select transistor ST1 is connected to the bit line BL. The source of the select transistor ST2 is connected to a source line SL.

The control gates of the memory cell transistors MC0 to MC7 in the same block BLK are commonly connected to the word lines WL0 to WL7, respectively. More specifically, for example, the block BLK includes four string units SU0 to SU3. Each string unit SU includes a plurality of memory cell transistors MC0. The control gates of the memory cell transistors MC0 in the block BLK are commonly connected to one word line WL0. This applies similarly to the memory cell transistors MC1 to MC7.

The gates of the select transistors ST1 in the string unit SU are commonly connected to one select gate line SGD. More specifically, the gates of the select transistors ST1 in the string unit SU0 are commonly connected to the select gate line SGD0. The gates of the select transistors ST1 in the string unit SU1 are commonly connected to the select gate line SGD1. The gates of the select transistors ST1 in the string unit SU2 are commonly connected to the select gate line SGD2. The gates of the select transistors ST1 in the string unit SU3 are commonly connected to the select gate line SGD3.

The gates of the select transistors ST2 in the block BLK are commonly connected to the select gate line SGS.

The word lines WL0 to WL7, the select gate lines SGD0 to SGD3, and the select gate line SGS are each connected to the row decoder 23.

The bit line BL is commonly connected to one NAND string NS in each string unit SU of each block BLK. Each bit line BL is connected to the sense amplifier 24.

The source line SL is, for example, shared by the blocks BLK.

### 1.4.3 Sectional Structure of Semiconductor Device

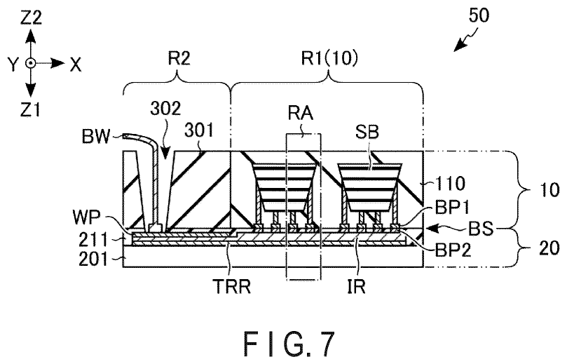

Next, referring to FIG. 7, an example of the sectional structure of the semiconductor device 50 is described. FIG. 7 is a sectional view showing an example of the sectional structure of the semiconductor device 50.

In the following description, a plane on which the circuit chip 20 and the array chip 10 are bonded to each other is assumed as an XY plane. Directions in the XY plane that are orthogonal to each other are assumed as an X direction and a Y direction. A direction that is substantially perpendicular to the XY plane and points from the array chip 10 to the circuit chip 20 is assumed as a Z1 direction. A direction that is substantially perpendicular to the XY plane and points from circuit chip 20 toward the array chip 10 is assumed as a Z2 direction. In a case of not limiting whether the Z1 direction or the Z2 direction, it is represented as the Z direction.

As shown in FIG. 7, the semiconductor device 50 includes the array chip 10, the circuit chip 20, and a spacer 301.

The semiconductor device 50 in the present embodiment has the bonded structure where the array chip 10 and the circuit chip 20 are bonded to each other. The surface where the array chip 10 and the circuit chip 20 are bonded to each other is represented as “bonded surface BS”.

For example, the area of the array chip 10 on the bonded surface BS is smaller than the area of the circuit chip 20. In such a case, a region R1 in which the array chip 10 is bonded, and a region R2 in which the spacer 301 is formed are provided on the surface of the circuit chip 20 that faces the Z2 direction.

The circuit chip 20 includes a semiconductor substrate 201, an insulating layer 211, a transistor region TRR, a wiring layer region IR, a plurality of bonded pads BP2, and a bonding pad WP.

For example, the semiconductor substrate 201 is a silicon substrate, and is a silicon wafer.

The transistor region TRR is provided on the surface of the semiconductor substrate 201 that faces the Z2 direction. A plurality of transistors that constitute a plurality of circuits are provided in the transistor region TRR. That is, the transistors are provided on the semiconductor substrate 201.

The wiring layer region IR is a region in which a plurality of wiring layers for connecting the transistor region TRR and the bonded pad BP2 or the bonding pad WP to each other are provided. The wiring layer region IR is provided between the transistor region TRR, and the bonded pad BP2 and the bonding pad WP.

The bonded pad BP2 is provided such that its surface that faces the Z2 direction is exposed on the bonded surface BS. In other words, the surface of the bonded pad BP2 that faces the Z2 direction is exposed from the insulating layer 211. The bonded pad BP2 is bonded to the bonded pad BP1 provided for the array chip 10. The bonded pad BP2 contains, for example, copper (Cu).

The bonding pad WP is provided in the insulating layer 211. An opening region of the bonding pad WP is provided in the region R2. In the opening region, part of the surface of the bonding pad WP that faces the Z2 direction is exposed. The bonding pad WP functions as an external connection terminal that is electrically connected to another chip, a substrate or the like. For example, a bonding wire BW is connected to the bonding pad WP. The bonding pad WP contains, for example, conductive metal, such as aluminum (Al).

The insulating layer 211 is provided on the surface of the semiconductor substrate 201 that faces the Z2 direction. For example, the insulating layer 211 covers the transistor region TRR and the wiring layer region IR. The insulating layer 211 contains silicon oxide.

The array chip 10 includes a stacked body SB, an insulating layer 110, and a plurality of bonded pads BP1.

The stacked body SB has a structure including a plurality of wiring layers and a plurality of insulating layers which are alternately stacked on a one-by-one basis. The stacked body SB corresponds to one memory cell array 11. In the example shown in FIG. 7, the array chip 10 includes two stacked bodies SB, i.e., two memory cell arrays 11. The details of the structure of the stacked body SB (memory cell array 11) are described later.

The bonded pad BP1 is provided such that its surface that faces the Z1 direction is exposed on the bonded surface BS. In other words, the surface of the bonded pad BP2 that faces the Z1 direction is exposed from the insulating layer 110. For example, the bonded pad BP1 is electrically connected to the memory cell array 11 provided in the stacked body SB. The bonded pad BP1 is bonded to the bonded pad BP2 provided for the circuit chip 20. The bonded pad BP1 contains, for example, copper. The array chip 10 and the circuit chip 20 are electrically connected to each other via the bonded pads BP1 and BP2.

The insulating layer 110 is provided so as to cover the stacked body SB. The insulating layer 110 contains silicon oxide.

The spacer 301 is provided in the region R2 of the circuit chip 20. The spacer 301 flattens a step portion due to the difference between the areas of the circuit chip 20 and the array chip 10. The surface of the spacer 301 that faces the Z2 direction is substantially parallel to the surface of the array chip 10 that faces the Z2 direction. The spacer 301 is provided with an opening 302 that allows the bonding pad WP of the circuit chip 20 to be exposed. For example, the bonding wire BW passes through the opening 302 and is connected to the bonding pad WP.

### 1.4.3.1 Sectional Structure of Array Chip

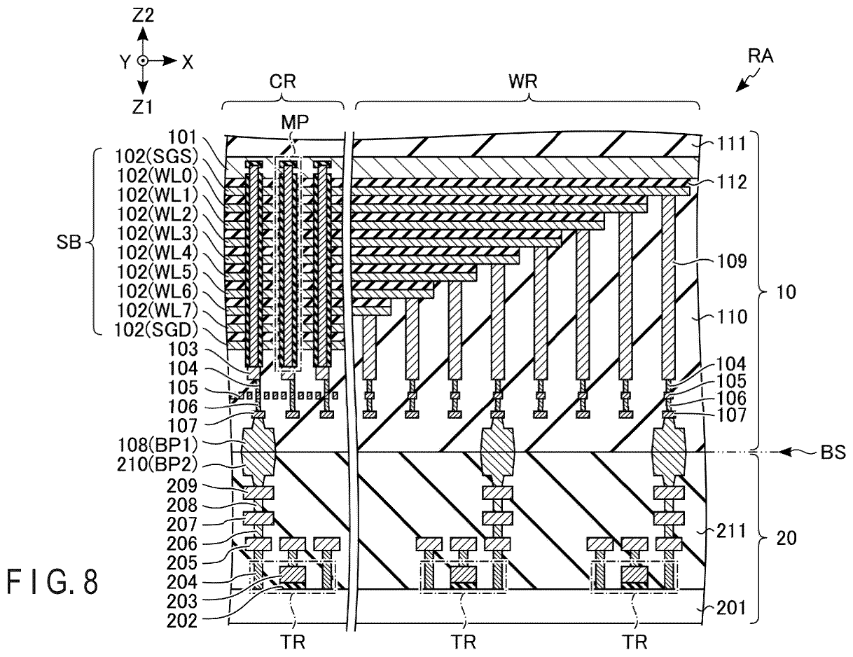

Next, referring to FIG. 8, an example of the sectional structure of the array chip 10 is described. FIG. 8 is a sectional view of a region RA in FIG. 7; The following description focuses on the section (hereinafter also represented as “memory cell array region”) of the region of the array chip 10 where the memory cell array 11 is provided.

As shown in FIG. 8, the array chip 10 includes: a semiconductor layer 101; wiring layers 102, 105, and 107; conductors 103, 104, 106, and 109; electrodes 108; insulating layers 110 to 112; and memory pillars MP.

The memory cell array 11 includes a cell region CR, and a WL connection region WR. The cell region CR is a region in which the memory cell transistors MC are disposed. The WL connection region WR is a connection region between the word lines WL and the select gate lines SGD and SGS, and contact plugs respectively corresponding thereto.

The semiconductor layer 101 is provided on the surface of the insulating layer 111 that faces the Z1 direction. The semiconductor layer 101 extends in the X direction and the Y direction. The semiconductor layer 101 in the memory cell array region functions as a source line SL. For example, insulating layer 111 contains silicon oxide (SiO) as an insulating material. For example, the semiconductor layer 101 contains silicon.

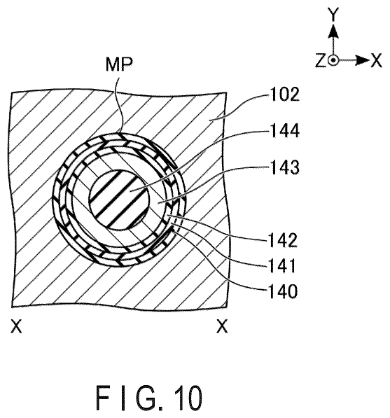

In the cell region CR, the insulating layers 112 and the wiring layers 102 are alternately stacked, on a one-by-one basis, on the surface of the semiconductor layer 101 that faces the Z1 direction. In the example shown in FIGS. 8, 10 insulating layers 112 and 10 wiring layers 102 are alternately stacked on a one-by-one basis. The stacked structure of the 10 insulating layers 112 and the 10 wiring layers 102 corresponds to the stacked body SB. The insulating layers 112 and the wiring layers 102 extend in the X direction. The insulating layer 112 contains, for example, silicon oxide. The wiring layer 102 contains, for example, tungsten (W) as a conductive material. In the example shown in FIG. 8, the 10 wiring layers 102 function as the select gate line SGS, the word lines WL0 to WL7, and the select gate line SGD, in the order from the side closer to the semiconductor layer 101.

In the WL connection region WR, the ends of the wiring layers 102 and the insulating layers 112 are drawn stepwise. The lengths of the wiring layers 102 in the X direction gradually decrease from the side closer to the semiconductor layer 101 toward the circuit chip 20.

The memory pillars MP are provided in the cell region CR. One memory pillar MP corresponds to one NAND string NS. The memory pillar MP has, for example, a columnar shape that extends in the Z direction. The memory pillar MP penetrates (passes) through the insulating layers 112 and the wiring layers 102. The end (bottom surface) of each memory pillar MP in the Z2 direction reaches the inside of the semiconductor layer 101. The details of the structure of the memory pillar MP is described later.

The insulating layer 110 is provided so as to cover the insulating layers 112, the wiring layers 102, and the memory pillar MP.

The conductors 109 are provided in the WL connection region WR. Each conductor 109 has, for example, a columnar shape that extends in the Z direction. The conductor 109 functions as a contact plug. The conductor 109 contains, for example, tungsten as a conductive material. The conductor 109 is connected to any one of the wiring layers 102, but is not electrically connected to the other wiring layers 102. The lengths of the conductors 109 in the Z direction are different depending on the corresponding wiring layers 102 to which they are respectively connected.

The conductor 103 is provided on the surface of the memory pillar MP that faces the Z1 direction. The conductor 103 has, for example, a columnar shape that extends in the Z direction. The conductor 103 functions as a contact plug. The conductor 103 contains, for example, tungsten as a conductive material.

The conductors 104 are provided on the surfaces of the conductors 103 in the cell region CR and the conductors 109 in the WL connection region WR that face the Z1 direction. The conductor 104 has, for example, a columnar shape that extends in the Z direction. The conductor 104 functions as a contact plug. The conductor 104 contains, for example, tungsten as a conductive material.

The wiring layer 105 is provided on the surface of each conductor 104 that faces the Z1 direction. For example, the wiring layers 105 in the cell region CR each extend in the Y direction and are arranged in the X direction. Each of the memory pillars MP is connected to any one of the wiring layers 105 via the corresponding conductors 103 and 104. The wiring layer 105 to which the memory pillar MP is connected functions as the bit line BL. The wiring layer 105 contains, for example, copper as a conductive material.

The conductor 106 is provided on the surface of the wiring layer 105 that faces the Z1 direction. The conductor 106 has, for example, a columnar shape that extends in the Z direction. The conductor 106 functions as a contact plug. The conductor 106 contains, for example, tungsten as a conductive material.

The wiring layer 107 is provided on the surface of each conductor 106 that faces the Z1 direction. The wiring layer 107 contains, for example, tungsten as a conductive material. Note that the conductors 106 and the wiring layers 107 may be formed by the dual damascene method. In the case of the dual damascene method, the patterns of the conductors 106 and the wiring layers 107 are collectively formed. The conductors 106 and the wiring layers 107 are collectively embedded in the conductive material (e.g., tungsten).

The surface of the insulating layer 110 that faces the Z1 direction is in contact with the insulating layer 211 of the circuit chip 20. That is, the surface on which the insulating layer 110 and the insulating layer 211 are in contact with each other is the bonded surface BS.

The electrode 108 is provided on the surface of the corresponding wiring layer 107 that faces the Z1 direction. Each electrode 108 contains, for example, copper as a conductive material. The electrodes 108 are formed by, for example, the dual damascene method. Each electrode 108 includes the bonded pad BP1, and the contact plug that connects the bonded pad BP1 and the wiring layer 107 to each other. The electrode 108 functions as the bonded pad BP1.

On the bonded surface BS, the bonded pad BP1 is in contact with the bonded pad BP2 provided in the circuit chip 20.

Note that the number of wiring layers 102 and the number of layers of the multi-layer wiring structure on the wiring layers 102 provided in the array chip 10 may be arbitrarily designed.

### 1.4.3.2 Sectional Structure of Circuit Chip

With continued reference to FIG. 8, the sectional structure of the circuit chip 20 is described.

The circuit chip 20 includes the semiconductor substrate 201, the transistors TR, the gate insulating films 202, the gate electrodes 203, the conductors 204, the wiring layers 205, 207, and 209, the conductors 206 and 208, the electrode 210, and the insulating layer 211.

As shown in FIG. 8, the transistors TR are provided on the surface of the semiconductor substrate 201 that faces the Z2 direction. A region where the transistors TR are provided corresponds to the transistor region TRR. Each transistor TR includes the gate insulating film 202, the gate electrode 203, and the source and the drain that are formed in the semiconductor substrate 201 but are not shown. The gate insulating film 202 is provided on the surface of the semiconductor substrate 201 that faces the Z2 direction. The gate electrode 203 is provided on the surface of the gate insulating film 202 that faces the Z2 direction.

The conductors 204 are provided on the surfaces of the gate electrodes 203 and the semiconductor substrate 201 that face the Z2 direction. Each conductor 204 has, for example, a columnar shape that extends in the Z direction. The conductor 204 functions as a contact plug. The conductor 204 contains, for example, tungsten.

The wiring layer 205 is provided on the surface of each conductor 204 that faces the Z2 direction. The wiring layer 205 contains, for example, tungsten as a conductive material.

The conductor 206 is provided on the surface of the corresponding wiring layer 205 that faces the Z2 direction. The conductor 206 has, for example, a columnar shape that extends in the Z direction. The conductor 206 functions as a contact plug. The conductor 206 contains, for example, tungsten or copper as a conductive material.

The wiring layer 207 is provided on the surface of the conductor 206 that faces the Z2 direction. The wiring layer 207 contains, for example, tungsten or copper as a conductive material. Note that the wiring layers 207 and the conductors 206 may be collectively formed by the dual damascene method.

The conductor 208 is provided on the surface of the corresponding wiring layer 207 that faces the Z2 direction. The conductor 208 has, for example, a columnar shape that extends in the Z direction. The conductor 208 functions as a contact plug. The conductor 208 contains, for example, copper as a conductive material.

The wiring layer 209 is provided on the surface of each conductor 208 that faces the Z2 direction. The wiring layer 209 contains, for example, copper as a conductive material. Note that the wiring layers 209 and the conductors 208 may be collectively formed by the dual damascene method.

The insulating layer 211 is provided on the surface of the semiconductor substrate 201 that faces the Z2 direction. The insulating layer 211 covers the transistors TR, the conductors 204, the wiring layers 205, the conductors 206, the wiring layers 207, the conductors 208, and the wiring layers 209. The surface of the insulating layer 211 that faces the Z2 direction is in contact with the insulating layer 110 of the array chip 10.

The electrode 210 is provided on the surface of the corresponding wiring layer 209 that faces the Z2 direction. Each electrode 210 contains, for example, copper as a conductive material. Each electrode 210 includes the bonded pad BP2, and the contact plug that connects the bonded pad BP2 and the wiring layer 209 to each other. The electrodes 210 are formed by, for example, the dual damascene method.

On the bonded surface, the bonded pad BP2 is in contact with the bonded pad BP1 provided in the array chip 10.

Note that the number of layers of the multi-layer wiring structure provided in the circuit chip 20 may be arbitrarily designed.

### 1.4.3.3 Sectional Structure of Memory Pillar

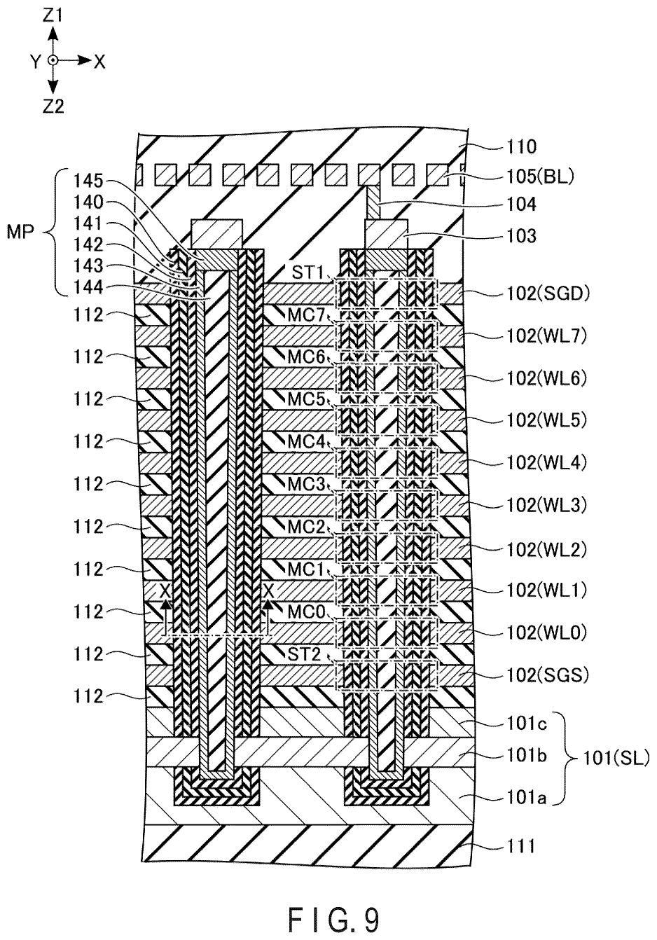

Next, referring to FIGS. 9 and 10, an example of the sectional structure of the memory pillar MP is described. FIG. 9 is a sectional view showing an example of the sectional structure of the cell region CR of the memory cell array 11. FIG. 9 shows two memory pillars MP included in the cell region CR of the memory cell array 11. FIG. 10 is a sectional view taken along line X-X of FIG. 9. More specifically, FIG. 10 shows the sectional structure of the memory pillar MP in the layer that includes the wiring layer 102 along the XY plane. The following description focuses on the structure of the memory pillar MP.

As shown in FIG. 9, the semiconductor layer 101 includes, for example, three semiconductor layers 101a, 101b, and 101c. The semiconductor layer 101b is provided on the surface of the semiconductor layer 101a that faces the Z1 direction. The semiconductor layer 101c is provided on the surface of the semiconductor layer 101b that faces the Z1 direction. The semiconductor layer 101b is formed by replacing a sacrificial layer provided between the semiconductor layer 101a and the semiconductor layer 101c, for example. The semiconductor layers 101a to 101c contain, for example, silicon. The semiconductor layers 101a to 101c contain, for example, phosphorus (P) as an impurity in the semiconductor.

The ten insulating layers 112 and the ten wiring layers 102 are alternately stacked, on a one-by-one basis, on the surface of the semiconductor layer 101 that faces the Z1 direction. That is, the stacked body SB is provided.

The insulating layer 110 is provided on the Z1-direction facing surface of the wiring layer 102 that functions as the select gate line SGD.

The memory pillars MP are provided in the cell region CR of the memory cell array 11. Each memory pillar MP penetrates through the 10 wiring layers 102. The bottom surface of each memory pillar MP reaches the semiconductor layer 101. Note that the memory pillar MP may have a structure where a plurality of pillars are coupled in the Z direction.

Next, the internal configuration of the memory pillar MP is described. The memory pillar MP includes a block insulating film 140, a charge storage film 141, a tunnel insulating film 142, a semiconductor film 143, a core film 144, and a cap film 145.

The block insulating film 140, the charge storage film 141, and the tunnel insulating film 142 are sequentially stacked on part of the side surface and the Z2-direction facing bottom surface of the memory pillar MP from the outside. More specifically, the block insulating film 140, the charge storage film 141, and the tunnel insulating film 142 on the side surface of the memory pillar MP are removed on the layer identical to or around the semiconductor layer 101b. The semiconductor film 143 is provided so as to be in contact with the side surface and the bottom surface of the tunnel insulating film 142, and the semiconductor layer 101b. The semiconductor film 143 is a region where the channels for the memory cell transistor MC and the select transistors ST1 and ST2 are formed. The inside of the semiconductor film 143 is embedded with the core film 144. At the upper portion of the memory pillar MP in the Z1 direction, the cap film 145 is provided on the upper ends of the semiconductor film 143 and the core film 144. The side surface of the cap film 145 is in contact with the tunnel insulating film 142. The cap film 145 contains, for example, silicon. The conductor 103 is provided on the surface of the corresponding cap film 145 that faces the Z1 direction. The conductor 104 is provided on the surface of the corresponding conductor 103 that faces the Z1 direction. The conductor 104 is connected to the wiring layer 105 that functions as the bit line BL.

The memory pillar MP and the wiring layers 102 functioning as the word lines WL0 to WL7 are combined, thus constituting the memory cell transistors MC0 to MC7. Likewise, the memory pillar MP and the wiring layer 102 functioning as the select gate line SGD are combined, thus constituting the select transistor ST1. The memory pillar MP and the wiring layer 102 functioning as the select gate line SGS are combined, thus constituting the select transistor ST2. Thus, each memory pillar MP can function as one NAND string NS.

An example of the sectional structure of the memory pillar MP along the XY plane is described.

As shown in FIG. 10, on the section including the wiring layer 102, the core film 144 is provided at the center of the memory pillar MP, for example. The semiconductor film 143 surrounds the side surface of the core film 144. The tunnel insulating film 142 surrounds the side surface of the semiconductor film 143. The charge storage film 141 surrounds the side surface of the tunnel insulating film 142. The block insulating film 140 surrounds the side surface of the charge storage film 141. The wiring layer 102 surrounds the side surface of the block insulating film 140.

The semiconductor film 143 is used as the channels (current paths) for the memory cell transistors MC0 to MC7 and the select transistors ST1 and ST2. The tunnel insulating film 142 and the block insulating film 140 each contain, for example, silicon oxide. The charge storage film 141 has a function of storing charges. The charge storage film 141 includes, for example, silicon nitride (SiN).

### 1.4.4 Semiconductor Device Manufacturing Method

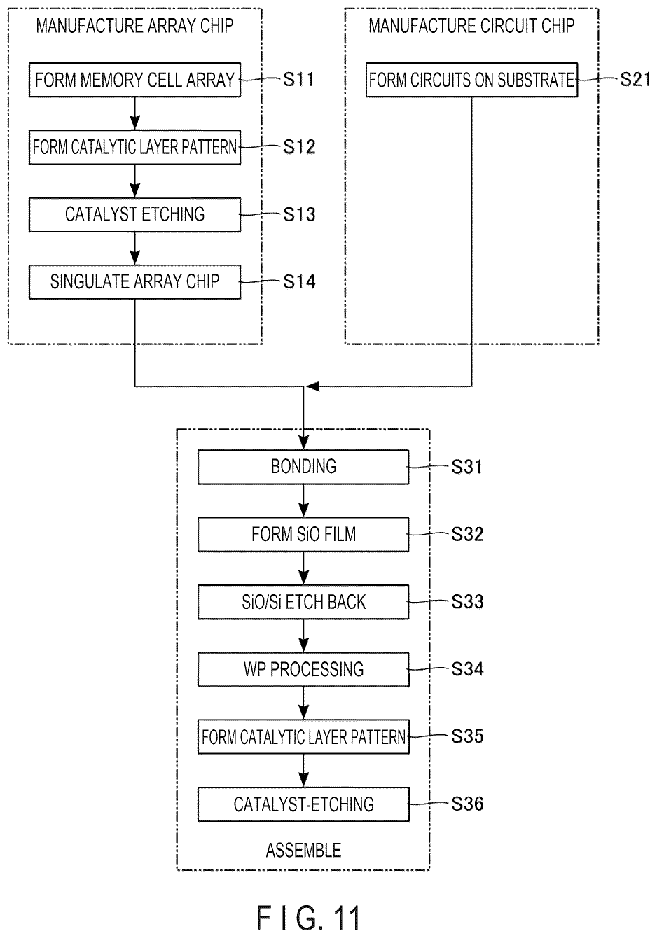

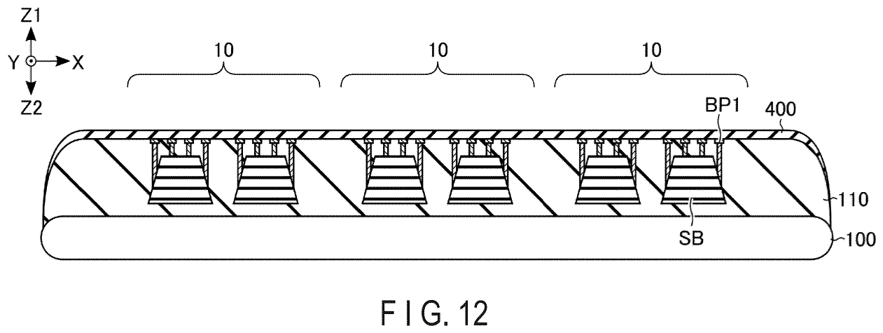

Next, referring to FIGS. 11 to 20, an example of a method of manufacturing the semiconductor device 50 is described. FIG. 11 is a flowchart showing an example of the method of manufacturing the semiconductor device 50. FIGS. 12 to 20 are sectional views showing the steps of manufacturing the semiconductor device 50. The following description focuses on the manufacturing steps and assembling steps for the array chip.

As shown in FIG. 11, the steps of manufacturing the semiconductor device 50 roughly include a step of manufacturing the array chip 10, a step of manufacturing the circuit chip 20, and an assembling step of bonding the array chip 10 and the circuit chip 20 to each other.

First, the step of manufacturing the array chip 10 is described. In the step of manufacturing the array chip 10, Steps S11 to S14 shown in FIG. 11 are sequentially executed.

### <Step S11>

As shown in FIG. 12, first, the memory cell array that includes the stacked bodies SB is formed on the semiconductor substrate 100. For example, the semiconductor substrate 100 is a silicon substrate, and is a silicon wafer. That is, the array chips 10 are formed on the silicon substrate. In the example shown in FIG. 12, the three array chips 10 arranged in the X direction are provided. For example, a protection film 400 is provided on the surfaces of the insulating layer 110 and the bonded pads BP1 that face the Z1 direction. Preferably, the protection film 400 is made of a material that prevents the bonded pads BP1 from being oxidized, and can be removed by catalyst-etching. Note that the protection film 400 may be omitted.

In the present embodiment, instead of cutting the array chips 10 formed on the semiconductor substrate 100 by dicing, catalyst etching described using Steps S12 and S13 is executed.

### <Step S12>

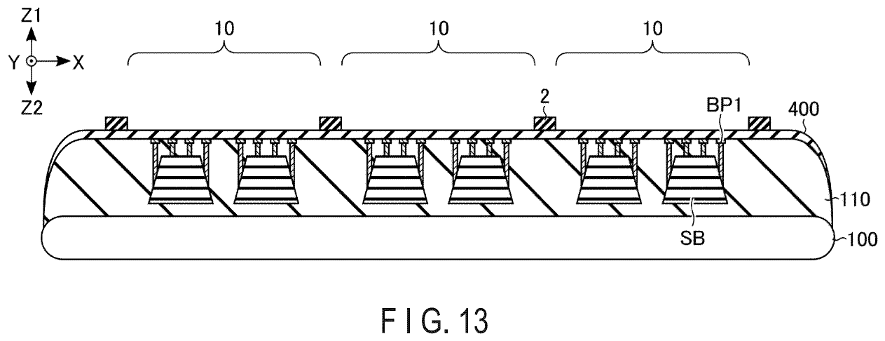

As shown in FIG. 13, a pattern of the catalytic layer 2 is formed on the protection film 400 to separate and singulate each chip. For example, in the case where the catalytic layer 2 is made of resist, the pattern is formed by photolithography as described with reference to FIG. 2 and the part (a) of FIG. 3. In cases where the catalytic layer 2 is not made of resist, the catalytic layer 2 is formed by etching as described with reference to FIG. 4, for example.

### <Step S13>

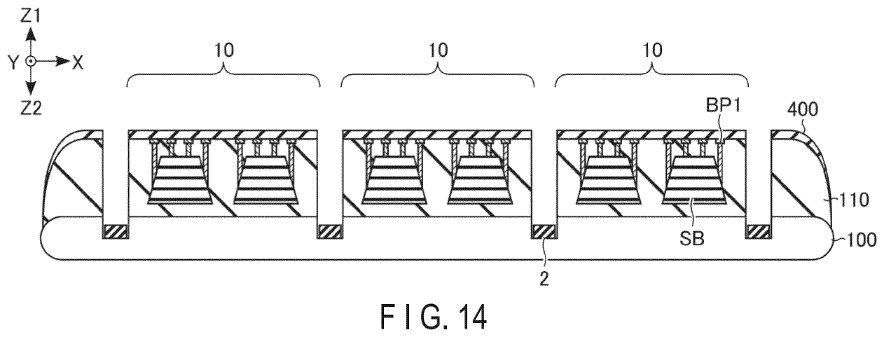

As shown in FIG. 14, the catalyst etching of the insulating layer 110 and the semiconductor substrate 100 is executed. More specifically, as described with reference to FIGS. 2 and 3, first, the insulating layer 110 (and the protection film 400) is etched in the HF gas atmosphere. Next, the back surface of the semiconductor substrate 100 is irradiated with UV light, and the semiconductor substrate 100 is etched also in the HF gas atmosphere. Note that in this stage, the semiconductor substrate 100 has not been separated yet. That is, grooves are formed in the semiconductor substrate 100.

After the catalyst etching, the catalytic layer 2 is removed.

### <Step S14>

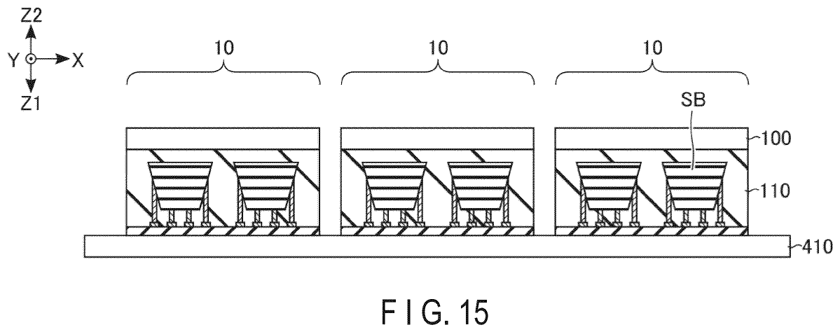

As shown in FIG. 15, the array chip 10 is singulated (separated). More specifically, BG (back grinding) protection tape 410 is pasted on the insulating layer 110 (protection film 400), and the back surface of the semiconductor substrate 100 is ground to form a thin-film substrate. Thus, the array chips 10 are each singulated. After the back surface grinding, tape for pickup is pasted on the ground surface of the semiconductor substrate 100. In this state, the BG protection tape 410 and the protection film 400 are removed.

Next, the steps of manufacturing the circuit chip 20 are simply described.

### <Step S21>

As shown in FIG. 11, the circuit chips 20 are formed on the semiconductor substrate 201. The area of the circuit chip 20 is greater than the area of the array chip 10. The circuit chips 20 having not been bonded yet are not singulated.

Next, the assembling steps are described. In the assembling steps, Steps S31 to S36 shown in FIG. 11 are sequentially executed.

### <Step S31>

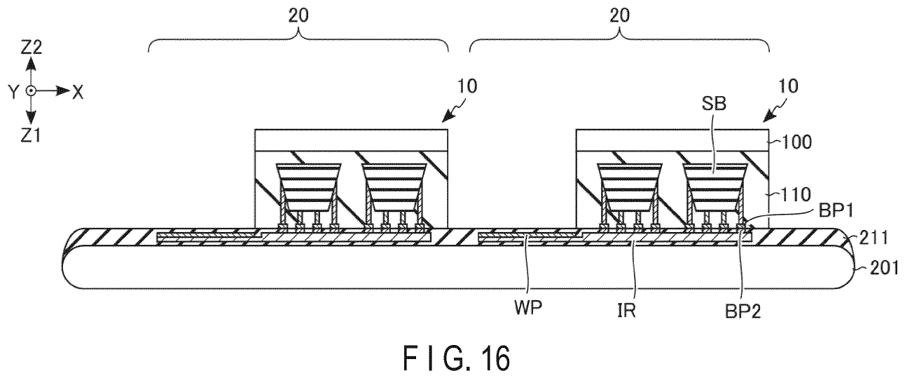

As shown in FIG. 16, the singulated array chips 10 are bonded onto the respective circuit chips 20 provided on the semiconductor substrate 201. The area of the circuit chip 20 is greater than the area of the array chip 10. Accordingly, the array chips 10 are sparsely present above the semiconductor substrate 201.

### <Step S32>

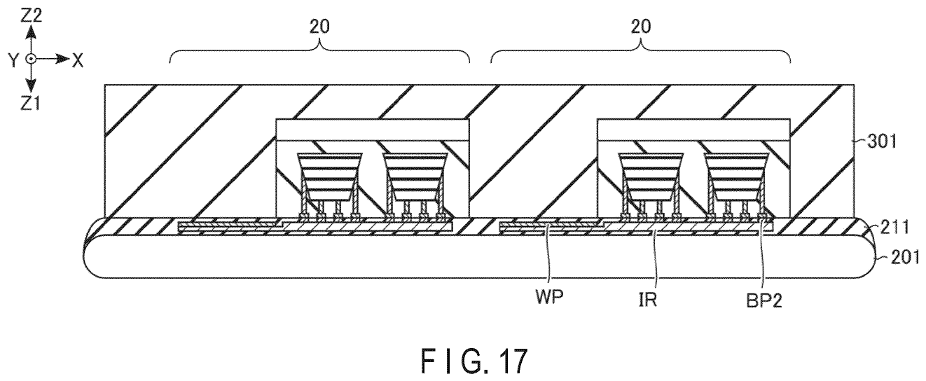

As shown in FIG. 17, to fill the gaps between the array chips 10, the spacer 301 is film-formed. The spacer 301 covers the surface of each array chip 10 that faces the Z2 direction.

### <Step S33>

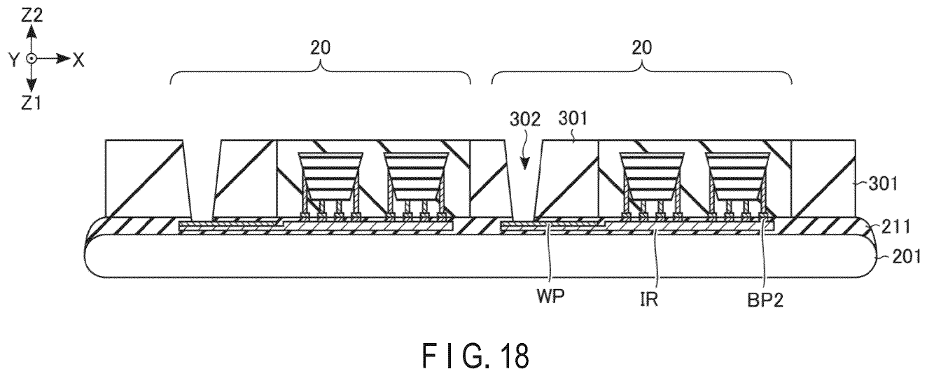

As shown in FIG. 18, the semiconductor substrate 100 of each array chip 10 and the spacer 301 thereon are removed. The removing method may be grinding, etch back by dry etching, CMP (Chemical Mechanical Polishing), or a combination of them. Accordingly, the surface of the spacer 301 that faces the Z2 direction is made to be substantially parallel to the surface of the array chip 10 that faces the Z2 direction.

### <Step S34>

As shown in FIG. 18, the opening 302 is formed, and the bonding pad WP is exposed. In the present embodiment, instead of cutting the semiconductor substrate 201 by dicing, catalyst etching described using Steps S35 and S36 is executed.

### <Step S35>

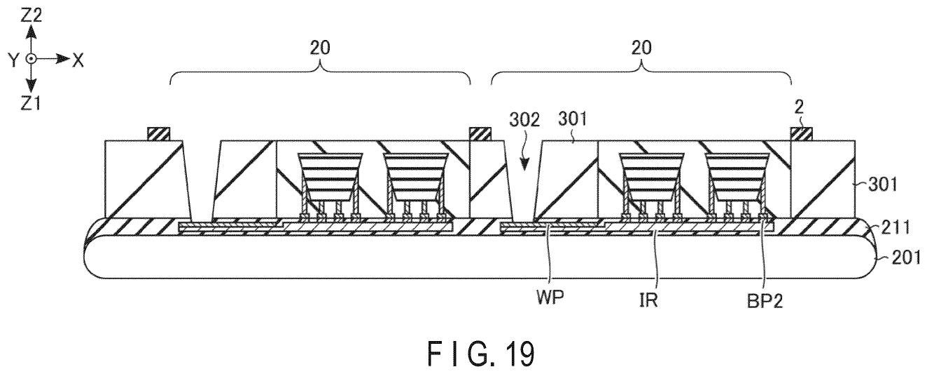

Similar to Step S12, the pattern of the catalytic layer 2 is formed on the spacer 301 as shown in FIG. 19. For example, in the case where the catalytic layer 2 is made of resist, the pattern is formed by photolithography as described with reference to FIG. 2 and the part (a) of FIG. 3. In cases where the catalytic layer 2 is not made of resist, the catalytic layer 2 is formed by etching as described with reference to FIG. 4, for example.

### <Step S36>

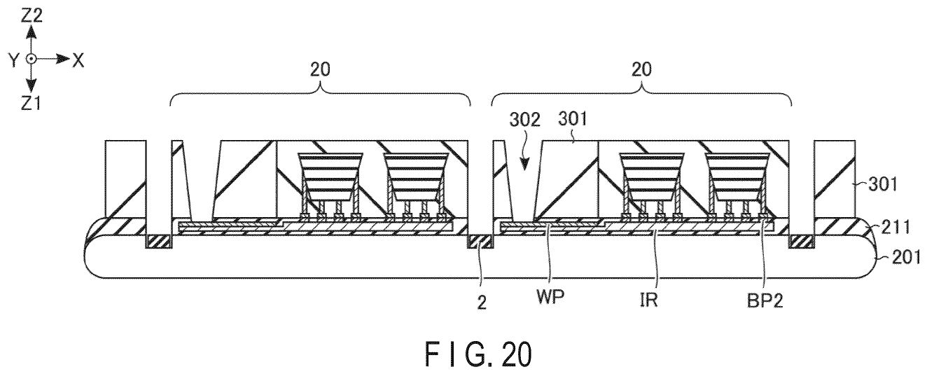

As shown in FIG. 20, the catalyst etching of the spacer 301, the insulating layer 211, and the semiconductor substrate 201 is executed. More specifically, as described with reference to FIGS. 2 and 3, first, the spacer 301 and the insulating layer 211 are etched in the HF gas atmosphere. Next, the back surface of the semiconductor substrate 201 is irradiated with UV light, and the semiconductor substrate 201 is etched also in the HF gas atmosphere. Accordingly, the circuit chips 20 are separated.

After the catalyst etching, the catalytic layer 2 is removed.

### 1.5 Advantageous Effects of Present Embodiment

According to the configuration of the present embodiment, a material that is hydrogen-bonded to HF gas can be used for the catalytic layer. Accordingly, silicon oxide in contact with the catalytic layer is preferentially etched by the HF gas. That is, the silicon oxide can be anisotropically etched by the catalytic layer.

Furthermore, according to the configuration of the present embodiment, by irradiating the silicon substrate with light having a wavelength of 1,100 nm or less (including UV light and visible light), holes can be generated in the silicon substrate. Accordingly, silicon in contact with the catalytic layer is preferentially etched by the HF gas. That is, the silicon can be anisotropically etched by the catalytic layer.

Furthermore, the configuration according to the present embodiment can apply catalyst etching to the dicing step of the semiconductor device manufacturing method. For example, in the case of plasma dicing, fluorocarbon (CF) gas is used. Accordingly, an environmental load due to CF gas occurs. Unlike this, the catalyst etching can reduce the environmental load. Since the fine catalytic layer pattern can be formed, the chip intervals on the semiconductor substrate can be reduced. Accordingly, the number of chips per semiconductor substrate can be increased. Consequently, the cost can be reduced.

### 2. Second Embodiment

Next, a second embodiment is described. In the second embodiment, an etching apparatus with catalyst etching is described. Differences from the first embodiment are mainly described below.

### 2.1 Configuration of Etching Apparatus

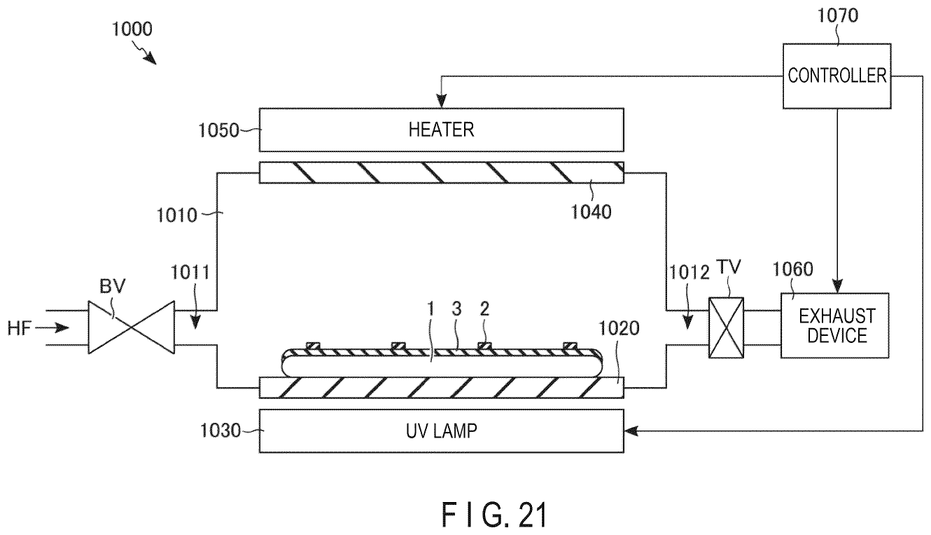

Referring to FIG. 21, an example of the configuration of an etching apparatus 1000 with catalyst etching is described. FIG. 21 shows the example of the configuration of the etching apparatus 1000 used for catalyst etching. The case where the etching apparatus 1000 is a semiconductor device manufacturing apparatus is described below. However, there is no limitation to this.

In the following description, in a state where the etching apparatus 1000 is installed, the gravity direction is defined as “downward/lower” and the opposite direction is defined as “upward/upper”. In the sectional view of the etching apparatus 1000, the lower side in the diagram indicates the lower side of the etching apparatus 1000, and the upper side in the diagram indicates the upper side of the etching apparatus 1000.

As shown in FIG. 21, the etching apparatus 1000 includes a chamber 1010, a stage 1020, a light source 1030, a heating window 1040, a heater 1050, an exhaust device 1060, a controller 1070, a valve BV, and a throttle valve TV.

The chamber 1010 is a processing chamber used for catalyst etching. The chamber 1010 is made of, for example, stainless steel. Note that the chamber 1010 may be made of another material. The chamber 1010 may have a configuration that can regulate the temperature of the inner wall of the chamber 1010 by a temperature regulating mechanism, not shown. For example, the chamber 1010 is provided with a gate valve, not shown. For example, the silicon substrate 1 is transferred from the outside of the chamber 1010 into the chamber 1010 through the gate valve. In the example shown in FIG. 21, the silicon substrate 1, where the silicon oxide 3 is formed on the upper surface and the catalytic layer 2 is provided on the silicon oxide 3, is mounted. Note that the substrate is not limited to the silicon substrate 1. The substrate may be made of a material other than silicon. It may be only required that a layer that can be etched by catalyst etching is formed on the substrate, and the catalytic layer 2 is provided thereon. That is, any substrate may be employed as long as the catalytic layer 2 is provided as the uppermost layer.

The chamber 1010 is provided with a supply port 1011 and an exhaust port 1012. The supply port 1011 is used to supply the HF gas into the chamber 1010. Note that a plurality of supply ports 1011 may be provided. For example, a supply port 1011 for supplying purge gas or the like may be separately provided. The supply port 1011 communicates with the valve BV. By the valve BV, turning on and off of gas supply into the chamber 1010 are controlled. The exhaust port 1012 is used to exhaust the gas in the chamber 1010. The exhaust port 1012 communicates with the exhaust device 1060 via the throttle valve TV. The gas in the chamber 1010 is exhausted through exhaust port 1012 to the exhaust device 1060. For example, the inside of the chamber 1010 is maintained at a reduced pressure (a pressure lower than the atmospheric pressure). Note that the pressure in the chamber 1010 may be the atmospheric pressure (ordinary pressure).

The stage (susceptor) 1020 is provided on the lower side of the chamber 1010. The silicon substrate 1 is mounted on the stage 1020. The upper surface of the stage 1020 is provided with a concave (seating) for allowing the silicon substrate 1 to be mounted therein. For example, the stage 1020 has a function as a transmissive window that transmits irradiation light from the light source 1030 provided below. The stage 1020 is made of, for example, quartz. Note that the stage 1020 may be made of any material as long as it can transmit irradiation light from the light source 1030.

The light source 1030 is provided below the stage 1020. The light source 1030 irradiates the back surface of the silicon substrate 1 with light. The silicon substrate 1 generates holes h⁺ by the irradiation light from the light source 1030. The irradiation light from the light source 1030 may be UV light or visible light. Irradiation light with a wavelength of 1,100 nm or less can generate holes h⁺ in the silicon substrate 1. For example, the light source 1030 is in an off state during etching of silicon oxide, and is in an on state during etching of silicon. Note that the light source 1030 may be provided on the upper surface or a side surface of the chamber 1010. In this case, the upper surface or the side surface of the chamber 1010 is provided with a window for transmitting irradiation light. The stage 1020 does not necessarily have a function of transmitting the irradiation light.

At least part of the upper surface of the chamber 1010 is provided with the heating window 1040. The heating window 1040 transmits infrared light (thermal radiation light) emitted from the heater 1050 provided thereabove. For example, the heating window 1040 is made of quartz. Note that the heating window 1040 may be made of any material as long as it can transmit infrared light.

The heater 1050 is provided above the chamber 1010. The heater 1050 heats the silicon substrate 1 through the heating window 1040. For example, the heater 1050 is an IR (Infrared) heater that emits infrared light. Note that the heater 1050 may have any configuration. The heater 1050 may be of lamp heating, resistance heating, or induction heating. For example, during the catalyst etching, the silicon substrate 1 and the silicon oxide 3 are heated to be at 100° C. or higher and 400° C. or lower. For example, if water remains on the surfaces of the silicon substrate 1 and the silicon oxide 3 during the catalyst etching, the reaction between HF and Si (SiO) is promoted, and the etching selectivity due to the catalytic layer 2 decreases. Preferably, the silicon substrate 1 and the silicon oxide 3 are heated to 100° C. or higher in order to remove the water. For example, it is preferable to heat the silicon substrate 1 and the silicon oxide 3 to 400° C. or lower in consideration of the compatibility of the semiconductor device with manufacturing processes, and prevention of etching for the stage 1020 and the heating window 1040 due to the HF gas. Note that the heater 1050 may be provided on the lower surface or a side surface of the chamber 1010. In the case where the heater 1050 is provided below the chamber 1010, the stage 1020 has a function as the heating window 1040.

The exhaust device 1060 exhausts the gas in the chamber 1010. The exhaust device 1060 may have any configuration. For example, the exhaust device 1060 may include at least one of a turbomolecular pump, a mechanical booster pump, and a dry pump.

The controller 1070 controls the entire etching apparatus 1000. More specifically, for example, the controller 1070 controls the light source 1030, the heater 1050, the exhaust device 1060, the valve BV, and the throttle valve TV.

### 2.2 Advantageous Effects of Present Embodiment

According to the configuration of the present embodiment, the etching apparatus 1000 can irradiate the silicon substrate 1 with light having a wavelength of 1,100 nm or less, and cause the silicon substrate 1 to generate holes h⁺. Furthermore, the HF gas can be supplied into the chamber 1010. Accordingly, the etching apparatus that can execute catalyst etching described in the first embodiment can be provided.

### 3. Modified Example etc

An etching method according to the embodiment includes: a step of providing a catalytic layer (2) on a substrate (1) that has silicon as a principal component; a step of exposing the substrate (1) provided with the catalytic layer (2), to an HF gas atmosphere; and a step of irradiating the substrate (1) in the HF gas atmosphere with light, and etching the substrate (1) in contact with the catalytic layer (2).

According to the configuration of the embodiment, the etching method with using HF gas and a catalyst can be provided.

Note that without limitation to the embodiments described above, various modifications can be applied.

For example, the catalyst etching in the embodiment is also applicable to steps of manufacturing optical elements, such as an X-ray sensor and a two-dimensional photonic crystal. Furthermore, the catalyst etching is applicable to steps of manufacturing an electric circuit element, an optical element, MEMS (Micro Electro Mechanical Systems), a recording element, a sensor, a mold or the like. The electric circuit elements may include volatile or nonvolatile semiconductor memories, such as a DRAM (Dynamic Random Access Memory), an SRAM (Static Random Access Memory), and an MRAM (Magnetoresistive Random Access Memory), and semiconductor elements, such as an LSI (Large Scale Integration), a CCD (Charge Coupled Device), an image sensor, and an FPGA (Field Programmable Gate Array). The mold may be a mold for imprinting or the like.

Furthermore, “connection” in the embodiments also includes a state of indirect connection with intervention of a transistor, a resistor or any other element.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. An etching method, comprising:
providing a catalytic layer on a substrate, the substrate containing silicon as a principal component;
exposing the substrate with the catalytic layer thereon to an HF gas atmosphere; and
irradiating the substrate with light under the HF gas atmosphere to etch portions of the substrate that are in contact with the catalytic layer.

2. The etching method of claim 1, wherein the substrate includes a first layer containing silicon and oxygen or containing silicon and nitrogen;
providing the catalytic layer on the substrate includes forming the catalytic layer on the first layer; and
exposing the substrate and the catalytic layer to the HF gas atmosphere etches portions of the first layer that are in contact with the catalytic layer.

3. The etching method of claim 1, wherein the catalytic layer contains phenol.

4. The etching method of claim 1, wherein the catalytic layer contains a hydroxyl group (—OH), a carboxyl group (—COOH), an amino group (—NH₂), an amide group (—CONH₂), a nitro group (—NO₂), or an ether bond (—O—).

5. The etching method of claim 1, wherein the catalytic layer contains novolac resin, poly (vinylphenol), naphthoquinone diazide, phenolic low molecular weight oligomer, phenolic dendrimer, phenolic cyclic oligomer, resorcinol cyclic oligomer, naphthol cyclic oligomer, or dihydroxynaphthalene cyclic oligomer.

6. The etching method of claim 5, wherein the novolac resin includes phenol novolac resin, naphthol novolac resin, resorcinol novolac resin, or dihydroxynaphthalene novolac resin.

7. The etching method of claim 1, wherein the light has a wavelength of 1,100 nm or less.

8. The etching method of claim 1, wherein etching the substrate is performed at 100° C. or higher and 400° C. or lower.

9. A method of manufacturing a semiconductor device, the method comprising:
forming a first layer that contains silicon and oxygen, or contains silicon and nitrogen, on a substrate, the substrate containing silicon as a principal component;
providing a catalytic layer on the first layer;
exposing the substrate, the first layer, and the catalytic layer to an HF gas atmosphere to etch portions of the first layer that are in contact with the catalytic layer; and
irradiating the substrate with light under the HF gas atmosphere to etch portions of the substrate that are in contact with the catalytic layer, after etching the first layer.

10. The method of manufacturing the semiconductor device of claim 9, wherein:
the substrate includes a silicon wafer, and
the first layer contains silicon oxide.

11. The method of manufacturing the semiconductor device of claim 9, wherein etching the substrate includes performing a dicing.

12. The method of manufacturing the semiconductor device of claim 10, wherein the first layer includes a stacked body where a plurality of wiring layers and a plurality of insulating layers are alternately stacked.

13. The method of manufacturing the semiconductor device of claim 9, wherein:
a plurality of array chips are formed by etching the substrate, and
the method further comprises bonding the plurality of array chips to a circuit chip, the circuit chip including a wiring layer thereon.

14. The method of manufacturing the semiconductor device of claim 9, wherein the catalytic layer contains phenol.

15. The method of manufacturing the semiconductor device of claim 9, wherein the catalytic layer contains novolac resin, poly (vinylphenol), naphthol novolac, naphthoquinone diazide, phenolic low molecular weight oligomer, phenolic dendrimer, phenolic cyclic oligomer, resorcinol cyclic oligomer, naphthol cyclic oligomer, or dihydroxynaphthalene cyclic oligomer.

16. The method of manufacturing the semiconductor device of claim 15, wherein the novolac resin includes phenol novolac resin, naphthol novolac resin, resorcinol novolac resin, or dihydroxynaphthalene novolac resin.

17. The method of manufacturing the semiconductor device of claim 9, wherein the light has a wavelength of 1,100 nm or less.

18. An etching apparatus, comprising:
a chamber;
a stage in the chamber and on which a workpiece is mountable, the workpiece containing silicon and including a catalytic layer as an uppermost layer thereof;
a light source that is configured to irradiate the workpiece with light;
a heater that is configured to heat the workpiece;
a supply port on the chamber and through which HF gas is suppliable into the chamber; and
an exhaust port on the chamber and through which the chamber is exhaustable.

19. The etching apparatus of claim 16, wherein the heater is configured to heat the workpiece to a temperature of 100° C. or higher and 400° C. or lower.

20. The etching apparatus of claim 16, wherein the light has a wavelength of 1,100 nm or less.
